(19) United States
(12) Patent Application Publication
(10) Pub. No.: US 2018/0182878 A1
(43) Pub. Date: Jun. 28, 2018

(54) ENHANCEMENT-MODE TRANSISTOR COMPRISING AN AlGaN/GaN HETEROJUNCTION AND A P-DOPED DIAMOND GATE

(71) Applicant: COMMISSARIAT À L'ÉNERGIE ATOMIQUE ET AUX ÉNERGIES ALTERNATIVES, Paris (FR)

(72) Inventor: Erwan MORVAN, Montagne (FR)

(73) Assignee: COMMISSARIAT A L'ENERGIE ATOMIQUE ET AUX ENERGIES ALTERNATIVES, Paris (FR)

(21) Appl. No.: 15/759,437

(22) PCT Filed: Sep. 13, 2016
(86) PCT No.: PCT/EP2016/071538

§ 371 Date: Mar. 12, 2018

(30) Foreign Application Priority Data
Sep. 14, 2015 (FR) 15 58536

(51) Int. Cl. H01L 29/778; H01L 29/78; H01L 29/66; H01L 29/80; H01L 29/10; H01L 29/49; H01L 29/45; H01L 29/43; H01L 29/20; H01L 21/283; H01L 21/28

(52) U.S. Cl. CPC H01L 29/7786; H01L 29/78; H01L 29/66901; H01L 29/66477; H01L 29/66462; H01L 29/66431; H01L 21/28264; H01L 29/1066; H01L 29/4983; H01L 29/452; H01L 29/432; H01L 29/2003; H01L 21/283; H01L 29/80

(57) ABSTRACT

An enhancement-mode field-effect transistor comprising at least:
a heterojunction formed by at least one first layer comprising GaN and at least one second layer comprising AlGaN;
and a gate comprising P-doped diamond, such that a first part of the second layer of the heterojunction defining a channel of the transistor is arranged between the gate and the first layer of the heterojunction;
and in which the first part of the second layer of the heterojunction has a thickness of between approximately 5 nm and 12 nm and an aluminium content of between approximately 15% and 20%.

### TECHNICAL FIELD AND PRIOR ART

The invention relates to the field of enhancement-mode transistors (also called “normally-off”, or “n-off”, or “E-mode” transistors) comprising an AlGaN/GaN heterojunction. Such transistors correspond for example to power transistors of the HEMT (“High Electron Mobility Transistor”) type. The invention also relates to the field of electronic integrated circuits comprising such transistors.

The use of an AlGaN/GaN heterojunction in a power transistor such as an HEMT transistor is advantageous because of the high density of carriers (electrons) and the high mobility of these carriers obtained in the two-dimensional electron gas (2DEG, or “2 Dimensional Electron Gas”) of the transistor.

In such an enhancement-mode transistor comprising an AlGaN/GaN heterojunction, an p+ doped AlGaN or GaN portion is used to form the gate of the transistor, as is described for example in the document “Gate Injection Transistor (GIT)—A Normally-Off AlGaN/GaN Power Transistor Using Conductivity Modulation” by Y. Uemoto et al., Electron Devices, IEEE Transactions on, Vol. 54, Issue 12, December 2007, pages 3393-3399.

In certain configurations, for example like that described in the document “p-GaN Gate HEMTs with Tungsten Gate Metal for High Threshold Voltage and Low Gate Current” by I. Hwang et al., IEEE Electron Device Letters, vol.34, no 2, February 2013, the contact formed between the gate of the transistor and the metal portion positioned on the gate allowing the desired electric potential to be applied to the gate does not correspond to ohmic contact but to Schottky contact. This allows the threshold voltage of the transistor to be increased and the injection of holes, and thus the gate current, to be reduced. During the production of these transistors, the layer of p-doped AlGaN or GaN that is created in-situ by growth on the layer of AlGaN of the heterojunction must be etched in order to form the gate. However, the stopping of this etching on the layer of AlGaN of the heterojunction poses problems of selectivity and of control that generally lead to a degradation of the layer of AlGaN of the heterojunction and poor control of the passivation in the etched zones. This in particular has an effect on the two-dimensional electron gas, which manifests itself as an increase in the resistance in the on state of the transistor and a degradation of its uniformity, and also leads to trapping of charges in the etched zones. Finally, because of the quality and the mechanical stresses in the materials of this heterojunction, the addition of the p-doped layer made of AlGaN or of GaN onto the heterojunction also poses problems, in particular for the AlGaN.

The document “Nanocrystalline Diamond-Gated AlGaN/GaN HEMT” by T. J. Anderson et al., Electron Device Letters, IEEE, Vol.34, Issue 11, November 2013, pages 1382-1384, describes the manufacture of a depletion-mode HEMT transistor (also called “normally-on” or “n-on” or “Depletion-mode” transistor) in which a p-doped diamond gate is used to form a heat sink. The creation of such a diamond gate allows some of the problems related to the creation of a gate made of p-doped AlGaN or GaN to be overcome. However, the creation of the diamond gate described in this document involves significant thermal budgets (greater than 750° C.) that make the integration of such a gate into a method for manufacturing a transistor compatible with CMOS technology impossible. Moreover, the nucleation phase is more complex and does not allow the growth of p+ diamond in the immediate vicinity of the layer of AlGaN. The nucleation technique used also does not allow sufficiently conformal growth of the diamond to be obtained since it does not have the necessary conformality when it is carried out on a non-planar surface having a strong topology.

### DISCLOSURE OF THE INVENTION

One aim of the present invention is to propose an enhancement-mode transistor comprising an AlGaN/GaN heterojunction not having the disadvantages of the transistors of the prior art described above.

For this, the present invention proposes an enhancement-mode transistor comprising at least:
a heterojunction formed by at least one first layer comprising GaN and at least one second layer comprising AlGaN;
a gate comprising p-doped diamond and such that a first portion of the second layer of the heterojunction defining a channel of the transistor is positioned between the gate and the first layer of the heterojunction;
and wherein the first portion of the second layer of the heterojunction comprises a thickness between approximately 5 nm and 12 nm and a concentration of aluminium between approximately 15% and 20%.

The combined use of the gate made of p-doped diamond and of the specific layer of AlGaN of the heterojunction allows an enhancement-mode transistor to be made that does not have the problems related to a gate made of p-doped AlGaN or GaN, in particular those related to the creation of such a gate via epitaxy. The problems of etching selectivity during the etching of the gate are in particular solved through the use of p or p+ doped diamond.

The transistor according to the invention sensibly combines a gate of p or p+ doped diamond with a specific heterojunction that allows an enhancement-mode transistor having good performance to be obtained, and in particular a threshold voltage that can be between approximately 1V and 2V to be obtained. Finally, a transistor that comprises a p+ doped gate made of diamond combined with a heterojunction formed by a layer of GaN and a layer of AlGaN, the thickness of which is less than 5 nm and/or the aluminium concentration of which is less than 15%, would not allow sufficient performance to be obtained. Moreover, with a heterojunction formed by a layer of GaN and a layer of AlGaN, the thickness of which is greater than 12 nm and/or the aluminium concentration of which is greater than 20%, the transistor would have a threshold voltage Vth that is too low, less than 1V, and would not therefore be usable as an enhancement-mode transistor for power electronics that can both be completely blocked in the off state characterised by Vgs=0V and Vds=Vₙₒₘᵢₙₐₗ (for example 600V) and have a certain voltage tolerance Vgs between the on state (open) and the off state (blocked), that is to say, a threshold voltage Vth greater than 1V.

The fact that the first portion of the second layer of the heterojunction comprises a thickness between approximately 5 nm and 12 nm and an aluminium concentration between approximately 15% and 20% can allow the formation of a two-dimensional electron gas having a surface density of charges n_{S} less than approximately 4.10¹²cm⁻² that allows, combined with the gate of p-doped diamond, an enhancement-mode transistor to be formed.

Moreover, with respect to a gate made of AlGaN or GaN that must be doped with magnesium, the use of a gate made of diamond allows doping of the gate with boron to be carried out, which facilitates the implementation of this doping and allows a greater level of doping than that which can be obtained in a magnesium-doped gate made of AlGaN or of GaN to be easily obtained.

The expression “aluminium concentration” is used here to designate the molar fraction of AlN present in the AlGaN. For example, for Al_{0,2}Ga_{0,8}N, the aluminium concentration is 20%, which corresponds to approximately 10% aluminium atoms in the entire AlGaN (when taking into account the atoms of N). It can also be seen as the percentage of aluminium in the assembly formed by the atoms of aluminium and of gallium present in the AlGaN, without taking into account the atoms of N present in the AlGaN.

In a first case, the second layer of the heterojunction may comprise a substantially constant thickness between approximately 5 nm and 12 nm.

In a second case, the second layer of the heterojunction may comprise a thickness of less than approximately 35 nm, and second portions of the second layer of the heterojunction, adjacent to the first portion of the second layer of the heterojunction, may have thicknesses greater than that of the first portion of the second layer of the heterojunction.

In a third case, the second layer of the heterojunction may comprise at least one stack of at least one lower layer comprising AlGaN, a thickness between approximately 5 nm and 12 nm and an aluminium concentration between approximately 15% and 20%, and of at least one upper layer comprising AlGaN, a thickness such that the sum of the thicknesses of the lower layer and upper layer is less than approximately 35 nm, and an aluminium concentration between approximately 15% and 25%, and the first portion of the second layer of the heterojunction may correspond to a portion of the lower layer.

The second and third case in particular have the advantage of allowing source and drain accesses, or zones, of the transistor to be made from portions of AlGaN that are thicker and/or that comprise a greater concentration of aluminium than the portion of AlGaN located at the channel, which allows a greater surface density of charges and a lower resistance in the on state to be obtained without affecting the value of the threshold voltage that remains positive.

The doping of the diamond of the gate may be between approximately 3.10¹⁸ cm⁻³ and 3.10²¹ cm⁻³ and/or the thickness of the gate may be between approximately several tens of and several hundred nm, for example between approximately 50 nm and 300 nm. The thickness of the gate may be greater than the sum of the depleted zones in the p-doped diamond associated with the contact with the AlGaN of the second layer and with the contact with a gate metal, or metal contact, positioned on the doped diamond.

A metal contact may be positioned on the gate. This metal contact can in particular act as an electric contact for applying an electric potential to the gate.

The contact between this metal contact and the layer of p-doped diamond may be either ohmic or Schottky, in particular according to the level of doping of the diamond and the nature of the metal forming the metal contact. For example, this contact can be ohmic when this level of doping (acceptor concentration) is greater than approximately 10¹⁹ cm⁻³. Strong doping of the diamond can allow ohmic contact to be obtained and thus a GIT (“Gate Injection Transistor”) transistor to be obtained in which an injection of holes from the p-doped diamond to the channel of the transistor is desired in order to improve its performance in the on state of the transistor. Weaker doping allows Schottky contact to be obtained and thus a transistor to be obtained with a greater threshold voltage thus allowing the injection of holes to be greatly limited.

The first layer of the heterojunction may be directly in contact with the second layer of the heterojunction. The absence of AlN between the layers of the heterojunction allows in particular a good value of the threshold voltage of the transistor to be obtained.

The enhancement-mode transistor may further comprise at least:
a first passivation dielectric layer covering the second layer of the heterojunction;
two electric contacts passing through the first passivation dielectric layer and electrically connected to the source and to the drain of the transistor via the second layer of the heterojunction;
a second passivation dielectric layer covering the first passivation dielectric layer and the two electric contacts;
and the gate may pass through at least the first and second passivation dielectric layers.

The first layer of the heterojunction may be positioned on a substrate comprising Si and/or SiC and/or Al₂O₃ and/or sapphire. One or more other layers used for the growth of the first layer of the heterojunction may be positioned between the first layer of the heterojunction and the silicon substrate.

The invention also relates to an electronic circuit comprising at least one enhancement-mode transistor as described above.

The invention also relates to a method for manufacturing an enhancement-mode transistor, comprising at least the following steps:
creating a heterojunction formed by at least one first layer comprising GaN and at least one second layer comprising AlGaN;
creating a gate comprising p-doped diamond and such that a first portion of the second layer of the heterojunction defining a channel of the transistor is positioned between the gate and the first layer of the heterojunction;
and wherein the first portion of the second layer of the heterojunction comprises a thickness between approximately 5 nm and 12 nm and a concentration of aluminium between approximately 15% and 20%.

The method may further comprise, between the step of creating the heterojunction and the step of creating the gate, the implementation of the following steps:
deposition of at least one first passivation dielectric layer onto the second layer of the heterojunction;
creation of at least two first openings through the first passivation dielectric layer;
creation of at least two electric contacts at least in the two first openings and electrically connected to the source and to the drain of the transistor via the second layer of the heterojunction;
deposition of at least one second passivation dielectric layer onto the two electric contacts and onto the first passivation dielectric layer;
creation of at least one second opening passing through the first and second passivation dielectric layers and forming an access to the first portion of the second layer of the heterojunction;
and the gate may be made at least by carrying out the following steps:
creation of at least one layer of p-doped diamond in the second opening, on the first portion of the second layer of the heterojunction and on the second passivation dielectric layer;
etching of the p-doped diamond layer with stoppage on the second passivation dielectric layer, such that a remaining portion of the layer of p-doped diamond forms the gate.

The use of diamond to create the gate of the transistor allows, for its creation, the implementation of etching, for example O₂/Ar plasma etching, compatible with the standard CMOS methods and selective with respect to the second passivation dielectric layer onto which the layer of diamond is deposited.

In this case, the method may further comprise, between the creation of the second opening and the creation of the gate, a step of etching of a second portion of the second layer of the heterojunction located facing the second opening and covering the first portion of the second layer of the heterojunction.

Moreover, the second layer of the heterojunction may comprise a stack of at least one lower layer deposited on the first layer of the heterojunction and comprising AlGaN, a thickness between approximately 5 nm and 12 nm and an aluminium concentration between approximately 15% and 20%, and of at least one upper layer deposited on the lower layer and comprising AlGaN, a thickness such that the sum of the thicknesses of the lower layer and upper layer is less than approximately 35 nm, and an aluminium concentration between approximately 15% and 25%, and the first portion of the second layer of the heterojunction may correspond to a portion of the lower layer and the second portion of the second layer of the heterojunction may correspond to a portion of the upper layer.

The p-doped diamond may be made by carrying out the following steps:
formation of a nucleation layer;
conformal low-temperature growth of the p-doped diamond using the nucleation layer.

Such manufacturing of the gate made of p-doped diamond makes the manufacturing of the transistor compatible and integrable with standard CMOS technology.

### BRIEF DESCRIPTION OF THE DRAWINGS

The present invention will be better understood upon reading the description of examples of embodiments given for purely informational purposes in a way that is not at all limiting while referring to the appended drawings in which:

FIG. 1 schematically shows an enhancement-mode transistor comprising an AlGaN/GaN heterojunction and a gate of p-doped diamond, which is an object of the present invention, according to a first embodiment;

FIGS. 2A to 2C show examples of band diagrams of an enhancement-mode transistor comprising an AlGaN/GaN heterojunction and a gate of p-doped diamond, which is an object of the present invention;

FIGS. 3A to 3C show steps of a method for manufacturing an enhancement-mode transistor comprising an AlGaN/GaN heterojunction and a gate of p-doped diamond, which is also an object of the present invention, according to a first embodiment;

FIGS. 4A to 4C show steps of a method for manufacturing an enhancement-mode transistor comprising an AlGaN/GaN heterojunction and a gate of p-doped diamond, which is also an object of the present invention, according to a second embodiment.

Identical, similar or equivalent portions of the various drawings described below have the same numerical references in order to facilitate the passage from one drawing to another.

The various portions shown in the drawings are not necessarily shown on the same scale, in order to make the drawings more readable.

The various possibilities (alternatives and embodiments) must be understood as not being exclusive of each other and can be combined together.

### DETAILED DISCLOSURE OF SPECIFIC EMBODIMENTS

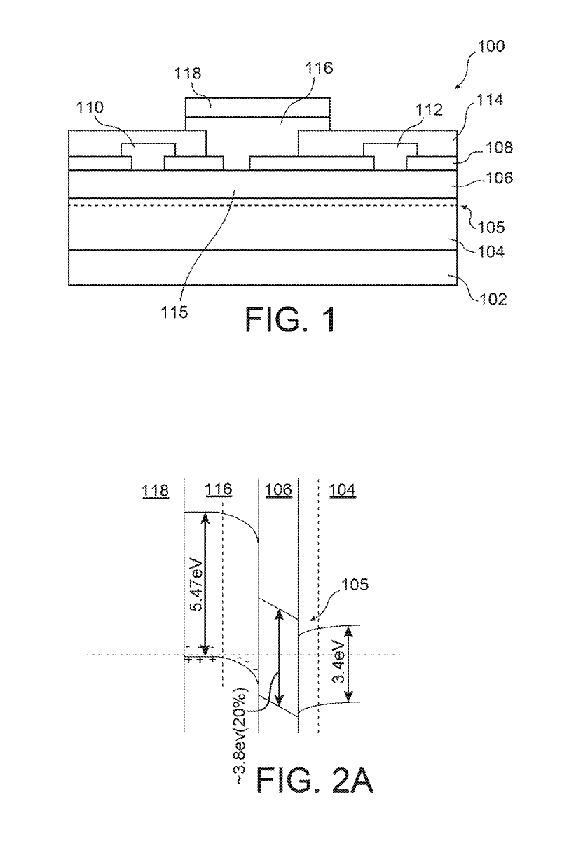

First of all, reference is made to FIG. 1, which corresponds to a schematic cross-sectional view of an enhancement-mode transistor 100, here of the HEMT type, comprising an AlGaN/GaN heterojunction and a gate made of p-doped diamond according to a first embodiment.

The transistor 100 is made from a semiconductor substrate 102, comprising for example silicon, on which the heterojunction of the transistor 100 is made. The substrate 102 may also comprise SiC or even Al₂O₃ or sapphire. This heterojunction comprises a first layer 104 comprising GaN and formed on the substrate 102, and a second layer 106 comprising AlGaN and formed on the first layer 104.

Although not visible in FIG. 1, a plurality of layers used for the growth of the materials of the heterojunction are positioned between the substrate 102 and the first layer 104. An example of an embodiment of these layers is described here: a first layer of AlN used as a nucleation layer can be formed at first on the substrate 102. A plurality of transition layers, comprising for example AlGaN, the aluminium concentration of which varies from one layer to another (for example a plurality of layers of AlGaN with a molar fraction of AlN that decreases when moving away from the substrate 102, or a superlattice comprising a plurality of Al_{X}Ga_{1-X}N/GaN bilayers), are positioned on the nucleation layer in order to create insulation and an adaptation of the crystal lattice parameter and manage the mechanical stresses between the substrate and the layers of the heterojunction. A thick buffer layer, for example several microns thick, is positioned on the transition layers in order to limit the lateral and vertical leakage currents in the transistor 100 and also better confine the two-dimensional electron gas. This thick buffer layer comprises for example GaN-SI (SI meaning semi-insulating) doped with carbon, or a GaN-SI/Al_{X}Ga_{1-X}N bilayer with X between approximately 4% and 8%. The layer 104 here comprising n.i.d. (non-intentionally doped) GaN is then formed on the buffer layer. Such intermediate layers allowing the creation of the heterojunction are for example described in the document US 2002/0074552 A1.

Optionally, it is possible for a fine layer of GaN (several nanometres thick) to be positioned between the buffer layer and the layer 104. Also optionally, in-situ SiN passivation can be carried out, deposited in the growth builds of the GaN.

The aluminium concentration of the AlGaN of the second layer 106 is between approximately 15% and 20%. The thickness of the layer 106 is between approximately 5 nm and 12 nm. The thickness of the layer 104 is chosen according to the breakdown voltage desired for the transistor 100, and is for example between approximately 1 μm and 15 μm. A two-dimensional electron gas 105 is formed in the first layer 104, under the interface between the first layer 104 and the second layer 106 (this two-dimensional electron gas is symbolically defined in the first layer 104 by the dotted lines in FIG. 1), at the channel and the source and drain of the transistor 100.

A first passivation dielectric layer 108, comprising for example SiN, covers the second layer 106. Two source and drain electric contacts, labelled 110 and 112, respectively, for example metal, are formed through the first passivation dielectric layer 108 and are in contact with regions of the second layer 106 forming accesses to the source and to the drain of the transistor 100. A second passivation dielectric layer 114, comprising for example SiO₂, covers the first passivation dielectric layer 108 and the electric contacts 110 and 112. When the transistor 100 is intended to act as a power transistor, each of the electric contacts 110 and 112 can be made in the form of a Ti/Al or Ta/Al bilayer. When the transistor 100 is intended to act as a transistor used in the microwave range, each of the electric contacts 110 and 112 can be made in the form of a Ta/Al or Ti/Al bilayer or in the form of a stack of Ti/Al/Ni/Au layers.

The transistor 100 also comprises a gate 116 positioned in an opening formed through the passivation dielectric layers 108 and 112 and such that it is directly in contact with a portion 115 of the second layer 106 defining the channel of the transistor 100. The gate 116 comprises p-doped nanocrystalline diamond (here doped with Boron), with a level of doping between approximately 3.10¹⁸ and 3.10²¹ cm⁻³ (which corresponds to a p+ level of doping). The thickness of the gate 116 is for example between approximately 50 nm and 500 nm. A metal portion 118 forming either ohmic contact with the gate 116 and comprising for example titanium or any other metal suitable for forming carbide during annealing, or Schottky contact and comprising for example TiN, is positioned on the gate 116.

The thickness and the composition of the material of the second layer 106 are such that they allow a two-dimensional electron gas 105 having a surface density of charges n_{S} lower than approximately 4.10¹² cm⁻² and a mobility of the electrons that is approximately 1900 cm²/(V.s), or between approximately 1300 and 2000 cm²/(V.s), to be obtained in the first layer 104, thus allowing the transistor 100 to have low resistance in the on state. The characteristics of the gate 116 of diamond contribute to the transistor 100 being an enhancement-mode transistor. In order for the threshold voltage to be positive and as high as possible, the p doping of the diamond in contact with the second layer 106 of AlGaN is high in order for the diffusion voltage (Vbi or V_{built-in}) to be maximum (Na>3.10¹⁸). From this doping, a thickness of p+ doped diamond that is much greater than that of the depletion zone formed in the diamond is deduced in order for there to remain a thickness of conductive diamond sufficient to provide an equipotential gate. In practice, the thickness of p+ diamond can be greater than approximately 50 nm.

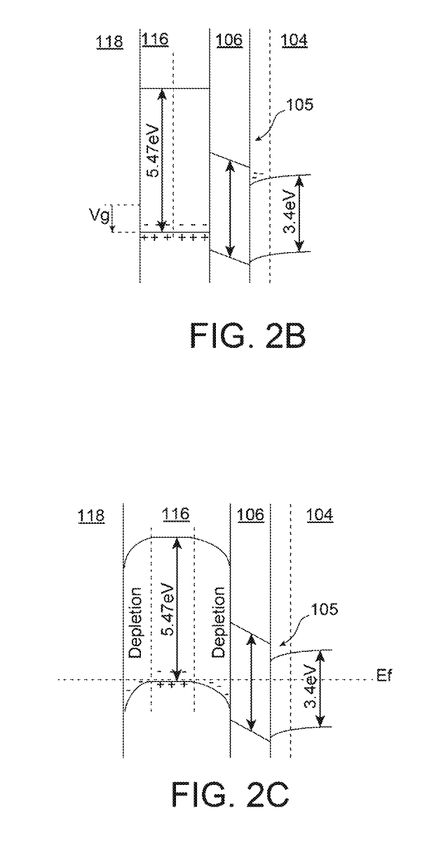

FIGS. 2A and 2B show the band diagrams of the transistor 100 in the portions of the various layers located facing the gate 116, for the case in which a zero voltage is applied to the gate 116 (via the metal contact 118) in order for the transistor 100 to be in a blocked state (FIG. 2A), and for the case in which a positive voltage greater than the threshold voltage of the transistor 100 is applied to the gate 116 in order for the transistor 100 to be in an on state (FIG. 2B). These diagrams correspond to those of a transistor 100 comprising a layer 106 having an Al_{0,2}Ga_{0,8}N composition.

These diagrams show that when the transistor 100 is blocked, the two-dimensional electron gas 105 under the AlGaN/GaN interface of the layers 104 and 106 is depleted by the presence of the gate 116 made of p-doped diamond. When the transistor 100 is on, applying a positive voltage to the gate 116 and greater than the threshold voltage of the transistor 100 allows the two-dimensional electron gas 105 to be repopulated and thus the transistor 100 to be placed in the on state.

FIG. 2C shows the band diagram of the transistor 100 in the portions of the various layers located facing the gate 116 when the gate contact is Schottky contact (contrary to the diagrams of FIGS. 2A and 2B for which the gate contact is ohmic contact). The thickness of the diamond of the gate 116 is greater than in the case of ohmic contact since the thickness of the depletion zone caused by the Schottky contact between the metal contact 118 and the diamond of the gate 116 must be added. The thickness of diamond of the gate 116 is for example greater than approximately 100 nm.

The values of the thickness of the second layer 106 and the aluminium concentration of the AlGaN of the second layer 106 described above provide a sensible compromise between the reachable value of the threshold voltage (which is for example chosen as equal to approximately 2V), and the performance and robustness of the two-dimensional electron gas at the gate-drain and gate-source access zones of the transistor that form most of the resistance in the on state of the transistor.

In order to obtain a threshold voltage that is positive and as high as possible, no intermediate layer of AlN is deposited between the first layer 104 and the second layer 106 since such a layer of AlN would provide too much biasing and thus a surface density of charges that is too high under the gate 116. Moreover, in order to obtain such a threshold voltage, and thus in order for the surface density of charges to not be too high under the gate 116, the thickness of the second layer 106 is chosen to be less than or equal to approximately 12 nm and the material of this second layer 106 comprises an aluminium concentration less than or equal to approximately 20%. These parameters of the second layer 106 allow the appearance of piezoelectric and spontaneous biasing under the gate 116 to be limited, and thus the surface density of charges under the gate 116 to be limited, and also the density of crystal defects to be limited

With regard to the performance and the robustness of the two-dimensional electron gas 105, the aluminium concentration of the AlGaN of the second layer 106 is chosen to be greater than or equal to approximately 15% in order to have a sufficient surface density of charges in the portions of the second layer 106 peripheral to the portion 115 located under the gate 116, that is to say, in the zones of access to the source and to the drain of the transistor 100. This aluminium concentration greater than or equal to approximately 15% also allows the degradation of the confinement of the two-dimensional electron gas 105 in the first layer 104 and thus the degradation of the mobility of the two-dimensional electron gas 105 to be prevented. Finally, such an aluminium concentration greater than or equal to approximately 15% of the AlGaN of the second layer 106 allows this second layer 106 to be created via an epitaxy that guarantees the formation of a heterojunction and the appearance of a two-dimensional electron gas.

The thickness of the second layer 106 also has an effect on the performance and the robustness of the two-dimensional electron gas 105. This thickness is chosen here to be greater than or equal to approximately 5 nm in order for the epitaxy of the second layer 106 to be sufficiently robust.

Thus, with a second layer 106 having a thickness equal to approximately 10 nm and an aluminium concentration equal to approximately 15%, it is possible to obtain a threshold voltage of approximately 1.8V. In general, with a second layer 106 having a thickness between approximately 5 nm and 12 nm and comprising an aluminium concentration between approximately 15% and 20%, the threshold voltage of the transistor 100 is between approximately 1V and 2V because of the other parameters affecting the value of the threshold voltage (diamond/AlGaN interface states, nucleation layer of the diamond and profile of doping in the diamond).

In this first embodiment, the second layer 106 is not etched, which allows the problems related to the creation of the gate 116 (interface states contamination of the AlGaN and precise control of the thickness of AlGaN) to be avoided.

In such a transistor 100, it is possible (but not necessary) to carry out an injection of holes from the gate 116 to the channel when the voltage applied to the gate 116 exceeds the injection threshold, that is to say, is greater than the threshold voltage for the diode formed by the gate 116 to become conductive. This injection of holes causes a modulation of the conductivity under the gate 116 and allows the resistance in the on state to be reduced. Nevertheless, this requires having a structure for evacuating the carriers when the transistor 100 switches in the blocked state, which can make the structure of the transistor 100 more complex and risks slowing down the switching thereof. In this material, the lifetime of the injected holes is short, which leads to low or degraded efficiency of conductivity modulation. Moreover, the circuits for controlling the gate of the transistor 100 (drivers) are more complex since they have to be capable of managing this injection current. Finally, the gate current associated with this injection of carriers can generate additional losses of energy in the on state.

In order to limit the injection of holes, obtain a high positive threshold voltage (for example greater than approximately 2V) and a greater gate-voltage amplitude, it is possible to create Schottky contact between the metal contact 118 and the layer of gate diamond 116.

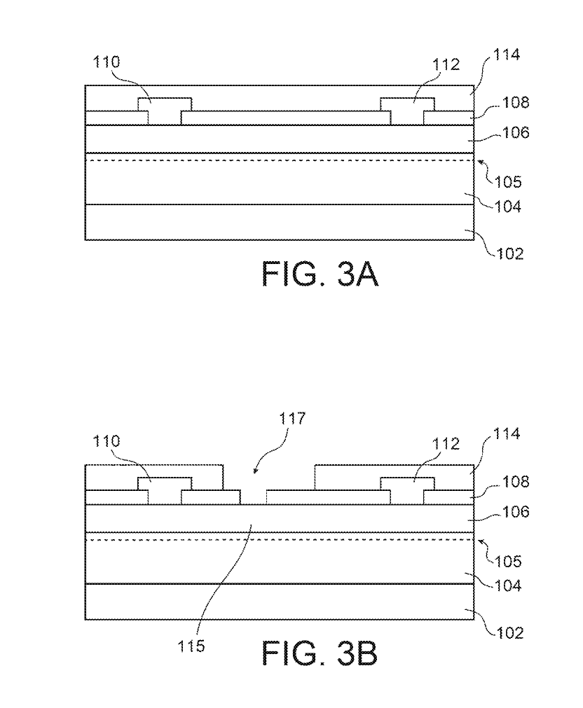

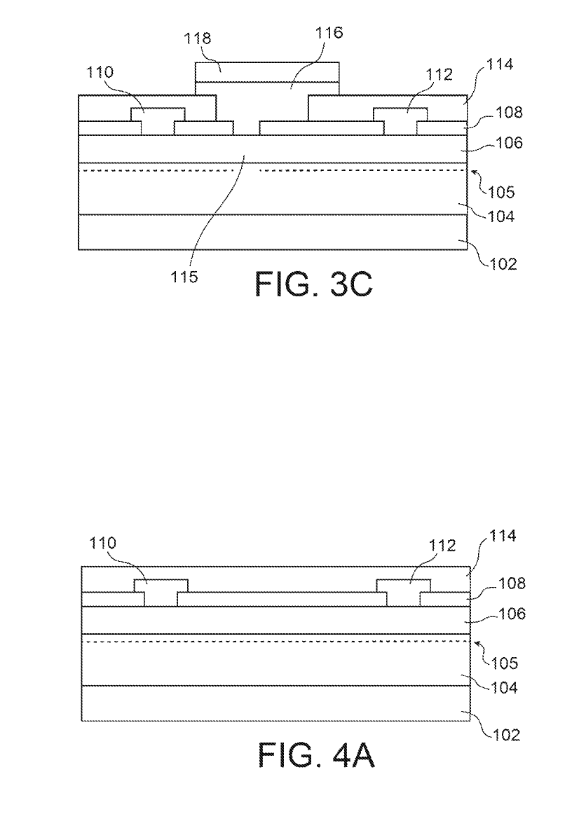

Steps of a method for manufacturing the transistor 100 according to the first embodiment are shown in FIGS. 3A to 3C.

As shown in FIG. 3A, the first layer 104 is made via epitaxial growth of GaN on the substrate 102 (by first forming, on the substrate 102, the various layers used for the growth of the first layer 104, as described above). The second layer 106 of AlGaN is then formed also via epitaxy on the first layer 104. The first passivation dielectric layer 108 is then deposited on the second layer 106.

Etching of the first passivation dielectric layer 108 is then implemented in order to form two first openings through the first passivation dielectric layer 108, these first openings forming accesses to the second layer 106. The electric contacts 110 and 112 are then created via deposition of a metal layer onto the first passivation dielectric layer 108 and in the first openings. This metal layer is then etched in order for remaining portions of this metal layer to form the electric contacts 110 and 112. Portions of the electric contacts 110 and 112 protrude onto the first passivation dielectric layer 108, at the periphery of the first openings.

The second passivation dielectric layer 114 is then deposited by covering the electric contacts 110, 112 and the first passivation dielectric layer 108.

As shown in FIG. 3B, a portion of the second passivation dielectric layer 114 is etched in order to form, in the layer 114, a second opening 117 forming a location of a first portion of the gate called “Field Plate”. A portion of the first passivation dielectric layer 108 is also etched in order to extend the second opening 117 into the layer 108 (however, with dimensions, in the plane of the layer 108, smaller than those in the plane of the layer 114) in order to form an access to the second layer 106 for a second portion of the gate called gate base. The etching of the first passivation dielectric layer 108 is carried out with stoppage on the AlGaN of the second layer 106.

A layer of p+ doped diamond is then created, for example via growth using a previously deposited nucleation layer, in the etched portions of the layers 108 and 114, that is to say, in the second opening 117 formed through the layers 108 and 114, and on the layer 114. A metal layer is then deposited on the layer of p+ doped diamond. Finally, the metal layer is etched, and then the layer of p+ doped diamond is etched for example via O₂/Ar plasma etching with stoppage on the layer 114, in order for the remaining portions of these layers to form the gate 116 and the metal gate contact 118 (FIG. 3C).

The gate 116 of p+ doped diamond is preferably made at low temperature, for example via steps using temperatures lower than approximately 700° C. or advantageously between approximately 500° and 600° C., which makes the creation of the gate 116 perfectly compatible with the presence of other elements made using CMOS technology on the substrate 102, without degrading the characteristics of these other elements. For this, a nucleation layer is created in a manner compatible with the techniques of microelectronics on silicon, and then conformal, low-temperature growth of the diamond is carried out using the nucleation layer. The document “Electrostatic grafting of diamond nanoparticles towards 3D diamond nanostructures” by H. A. Girard et al., Diamond and Related Materials 23 (2012), pp. 83-87, describes in particular details of creation of a low-temperature nucleation layer by a technique of electrostatic nucleation. Such a technique allows this nucleation layer to be created with good conformality with respect to the topology on which this layer is created. The growth of the diamond for example via MPCVD (“Microwave Plasma Chemical Vapour Deposition”) can be carried out as described in the document WO 2011/124568 A1. This growth is also carried out at low temperature and allows a layer of diamond having good conformality with respect to the topology on which it is created to be obtained.

The diamond of the gate 116 can also be made with the implementation of different techniques. Various techniques for CVD growth of the diamond are described in the document “Nanocrystalline Diamond Growth and Device Applications” by Michele Dipalo, Ulm University, 2 Oct. 2008.

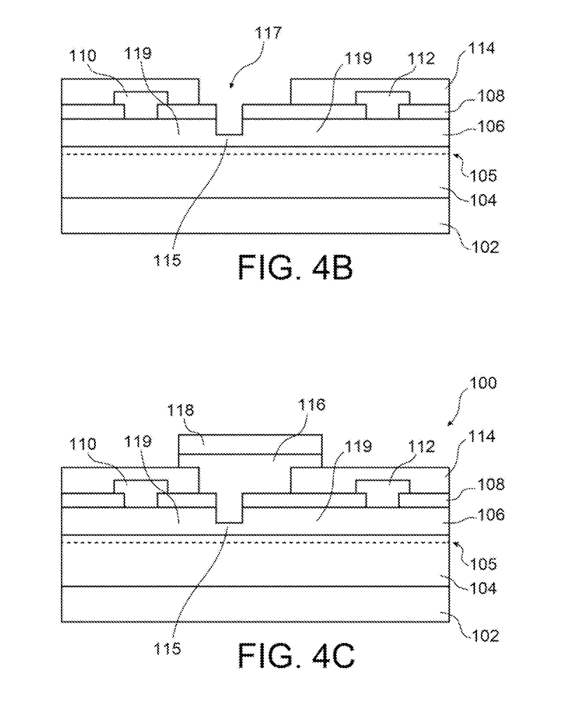

Steps of a method for manufacturing the transistor 100 according to a second embodiment are shown in FIGS. 4A to 4C.

First, the structure shown in FIG. 4A that is similar to that described above in relation to FIG. 3A is created.

Portions of the passivation dielectric layers 108 and 114 are then etched, as described above in relation to FIG. 3B, thus forming the second opening 117 through the passivation dielectric layers 108 and 114 (the second opening 117 comprising greater dimensions in the second passivation dielectric layer 114 than in the first passivation dielectric layer 108). However, contrary to the method described above in relation to FIGS. 3A to 3C, the etching is not stopped on the second layer 106 but is extended into a portion of the thickness of the AlGaN of the second layer 106 (FIG. 4B). Thus, the remaining thickness of AlGaN under the etched portion of the second layer 106 corresponds to the portion 115 of AlGaN having a thickness that is between approximately 5 nm and 12 nm and comprising an aluminium concentration between approximately 15% and 20% and which is intended to define the channel of the transistor 100. Second portions 119 of the second layer 106, adjacent to the first portion 115, thus have thicknesses greater than that of the first portion 115 and form access regions between the gate 116 and the source and drain of the transistor 100.

The transistor 100 is then finished by depositing the layer of p+ doped diamond in the etched portion of the second layer 106, in the second opening 117 formed in the passivation dielectric layers 108 and 114, and on the second passivation dielectric layer 114. The metal layer is then deposited on the layer of p+ doped diamond. Finally, the metal layer and the layer of p+ doped diamond are etched in order for the remaining portions of these layers to form the gate 116 and the metal gate contact 118 (FIG. 4C).

For the transistor 100 according to this second embodiment, the fact that the second layer 106 is partially etched at the gate 116 in order to form the portion 115 defining the channel of the transistor 100 allows the use of a second initial layer 106 thicker than in the first embodiment, and in particular having a thickness that can be greater than approximately 12 nm, advantageously between approximately 25 nm and 35 nm.

This second embodiment thus provides, at the gate 116, a thickness of AlGaN sufficiently fine for obtaining a positive threshold voltage while preserving, at the gate-source and gate-drain access regions, a greater thickness of AlGaN, for example between approximately 25 nm and 35 nm, and thus a greater surface density of charges and a resistance in the on state Ron lower than in the first embodiment. This second embodiment thus allows the constraints related to obtaining a threshold voltage that is positive and sufficiently high to be dissociated from those related to obtaining a sufficiently low resistance in the on state of the transistor.

In an alternative to the second embodiment described above, it is possible for the second layer 106 to correspond to a stack of at least one lower layer comprising AlGaN, positioned against the first layer 104 of GaN and comprising an aluminium concentration between approximately 15% and 20% and a thickness between approximately 5 nm and 12 nm, and of an upper layer of AlGaN that can in particular have and an aluminium concentration different than that of the AlGaN of the lower layer, for example greater than approximately 20% (for example equal to approximately 25%). The total thickness of this stack of the lower layer and of the upper layer is for example less than approximately 35 nm or between approximately 25 nm and 35 nm. In this alternative, the etching carried out through the stack of layers in order to create the gate 116, as described in FIG. 4B, is advantageously carried out through the entire thickness of the upper layer of AlGaN in order for the gate 116 to rest on the lower layer of AlGaN forming the portion 115 defining the channel of the transistor 100. The gate-source and gate-drain accesses are in this case formed by portions 119 of the lower and upper layers of AlGaN adjacent to the portion 115. The AlGaN of the upper layer of the stack allows these accesses to have a greater surface density of charges and a lower resistance in the on state Ron than in the first embodiment.

In an alternative to the two embodiments described above, it is possible to create the gate 116 before the creation of the first passivation dielectric layer 108. In this case, the layer of doped diamond must be etched selectively with respect to the AlGaN of the second layer 106 in order to form the gate 116, for example via O₂/Ar plasma etching.

Regardless of the embodiment and/or alternative embodiment of the transistor 100, such a transistor 100 can advantageously be part of electronic circuits used in the field of power electronics, for example in energy-conversion circuits used in electric cars or in photovoltaic devices, or for the control of industrial motors, or the power microwave field, for example in power microwave amplifiers used for radars or devices of telecommunications, or for carrying out logic functions that use integrated GaN technologies and manage for example the operation of power microwave amplifiers.

1. An enhancement-mode transistor comprising at least:
a heterojunction formed by at least one first layer comprising GaN and at least one second layer comprising AlGaN;
a gate comprising p-doped diamond and such that a first portion of the second layer of the heterojunction defining a channel of the transistor is positioned between the gate and the first layer of the heterojunction;
and wherein the first portion of the second layer of the heterojunction comprises a thickness between approximately 5 nm and 12 nm and a concentration of aluminium between approximately 15% and 20%.

2. The enhancement-mode transistor according to claim 1, wherein the second layer of the heterojunction comprises a substantially constant thickness between approximately 5 nm and 12 nm.

3. The enhancement-mode transistor according to claim 1, wherein the second layer of the heterojunction comprises a thickness of less than approximately 35 nm, and wherein second portions of the second layer of the heterojunction, adjacent to the first portion of the second layer of the heterojunction, have thicknesses greater than that of the first portion of the second layer of the heterojunction.

4. The enhancement-mode transistor according to claim 1, wherein the second layer of the heterojunction comprises at least one stack of at least one lower layer comprising AlGaN, a thickness between approximately 5 nm and 12 nm and an aluminium concentration between approximately 15% and 20%, and of at least one upper layer comprising AlGaN, a thickness such that the sum of the thicknesses of the lower layer and upper layer is less than approximately 35 nm, and an aluminium concentration between approximately 15% and 25%, and wherein the first portion of the second layer of the heterojunction corresponds to a portion of the lower layer.

5. The enhancement-mode transistor according to claim 1, wherein the doping of the diamond of the gate is between approximately 3.10¹⁸ cm⁻³ and 3.10²¹ cm⁻³ and/or the thickness of the gate is between approximately 50 nm and 300 nm.

6. The enhancement-mode transistor according to claim 1, wherein the first layer of the heterojunction is directly in contact with the second layer of the heterojunction.

7. The enhancement-mode transistor according to claim 1, further comprising at least:
a first passivation dielectric layer covering the second layer of the heterojunction;
two electric contacts passing through the first passivation dielectric layer and electrically connected to the source and to the drain of the transistor via the second layer of the heterojunction;
a second passivation dielectric layer covering the first passivation dielectric layer and the two electric contacts;
and wherein the gate passes through at least the first and second passivation dielectric layers.

8. The enhancement-mode transistor according to claim 1, wherein the first layer of the heterojunction is positioned on a substrate comprising at least one selected from the group consisting of Si, SiC, Al₂O₃ and sapphire.

9. An electronic circuit comprising at least one enhancement-mode transistor according to claim 1.

10. A method for manufacturing an enhancement-mode transistor, the method comprising:
creating a heterojunction formed by at least one first layer comprising GaN and at least one second layer comprising AlGaN;
creating a gate comprising p-doped diamond and such that a first portion of the second layer of the heterojunction defining a channel of the transistor is positioned between the gate and the first layer of the heterojunction;
and wherein the first portion of the second layer of the heterojunction comprises a thickness between approximately 5 nm and 12 nm and a concentration of aluminium between approximately 15% and 20%.

11. The method according to claim 10, further comprising, between the creating of the heterojunction and the creating of the gate:
depositing at least one first passivation dielectric layer onto the second layer of the heterojunction;
creating at least two first openings through the first passivation dielectric layer;
creating at least two electric contacts at least in the two first openings and electrically connected to the source and to the drain of the transistor via the second layer of the heterojunction;
depositing at least one second passivation dielectric layer onto the two electric contacts and onto the first passivation dielectric layer; and
creating at least one second opening passing through the first and second passivation dielectric layers and forming an access to the first portion of the second layer of the heterojunction;
and wherein the gate is made at least by carrying out the following:
creating at least one layer of p-doped diamond in the second opening, on the first portion of the second layer of the heterojunction and on the second passivation dielectric layer; and
etching of the p-doped diamond layer with stoppage on the second passivation dielectric layer, such that a remaining portion of the layer of p-doped diamond forms the gate.

12. The method according to claim 11, further comprising, between the creation of the second opening and the creation of the gate, etching a second portion of the second layer of the heterojunction located facing the second opening and covering the first portion of the second layer of the heterojunction.

13. The method according to claim 12, wherein the second layer of the heterojunction comprises a stack of at least one lower layer deposited on the first layer of the heterojunction and comprising AlGaN, a thickness between approximately 5 nm and 12 nm and an aluminium concentration between approximately 15% and 20%, and of at least one upper layer deposited on the lower layer and comprising AlGaN, a thickness such that the sum of the thicknesses of the lower layer and upper layer is less than approximately 35 nm, and an aluminium concentration between approximately 15% and 25%, and wherein the first portion of the second layer of the heterojunction corresponds to a portion of the lower layer and the second portion of the second layer of the heterojunction corresponds to a portion of the upper layer.

14. The method according to claim 10, wherein the p-doped diamond is made by carrying out the following:
forming a nucleation layer; and
performing conformal low-temperature growth of the p-doped diamond with the nucleation layer.
